(19) United States
(12) Patent Application Publication
(10) Pub. No.: US 2009/0146048 A1
(43) Pub. Date: Jun. 11, 2009

(54) PHOTO DETECTING APPARATUS

(75) Inventor: Tadashi CHIBA, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Tokyo (JP)

(21) Appl. No.: 12/211,298

(22) Filed: Sep. 16, 2008

(30) Foreign Application Priority Data
Sep. 19, 2007 (JP) 2007242470

(51) Int. Cl. H03F 3/08

(52) U.S. Cl. 250/214 A

(57) ABSTRACT

A photo detection apparatus includes first and second photo detection elements which are connected in series to each other at a junction node. A spectral response characteristic of the first photo detection element is different than a spectral response characteristics characteristic of the second photo detection element. The photo detection apparatus further includes a signal generating circuit connected to the junction node and generating a light detection signal corresponding to a current extracted at the junction node.

### BACKGROUND

1. Field of the Invention

The present invention generally relates to a photo detection apparatus for detecting an intensity of light irradiated on a frame of electronic equipment.

A claim of priority is made to Japanese patent application number 242470/2007, filed Sep. 19, 2007, the subject matter of which is incorporated herein by reference.

2. Description of the Related Art

Photo detecting devices have been utilized in electronic equipment (e.g., mobile phones) to detect ambient light in a surrounding environment of the equipment. Typically, a photo-detector is positioned in the equipment to detect the intensity of light passing through an aperture in the equipment.

The photo-detection accuracy of such devices is adversely influenced by so-call dark current. The causes of dark current are varied, and include the effects of stray light reflecting or scattering from an internal surfaces of the electronic equipment. Another source of dark current electrical variations of the detection circuitry caused by difference in ambient temperature.

Examples of attempts to detect irradiated light intensity while canceling out dark current are disclosed in Japanese Patent Application Laid Open Publication No.2007-52842, Japanese Patent Application Laid Open Publication No.H6-5888, and Japanese Patent Application Laid Open Publication No.H10-300574. Generally, these attempts are characterized by either the use of a shielding structure to minimize the effects of stray light, or separate photo-detection circuits generating separation detection outputs which may be processed to eliminate dark current. The shielding structure approach, however, suffers the drawback of increasing the space requirements within the electronic equipment. Further, relatively complex circuitry arrangements are necessary when incorporating separate photo-detection circuits.

### SUMMARY

According to an aspect of the present invention, a photo detection apparatus is provided. The photo detection apparatus includes first and second photo detection elements which are connected in series to each other at a junction node. A spectral response characteristic of the first photo detection element is different than a spectral response characteristics characteristic of the second photo detection element. The photo detection apparatus further includes a signal generating circuit connected to the junction node and generating a light detection signal corresponding to a current extracted at the junction node.

According to another aspect of the present invention, an electronic equipment is provided which includes a frame including an aperture, and a photo detecting apparatus located within the frame. The photo detecting apparatus includes first and second photo detection elements which receive incident photo energy through the aperture in the frame. The first and second photo detection elements are connected in series to each other at a junction node, and a spectral response characteristic of the first photo detection element is different than a spectral response characteristics characteristic of the second photo detection element. The photo detection apparatus further includes a signal generating circuit connected to the junction node and generating a light detection signal corresponding to a current extracted at the junction node.

### BRIEF DESCRIPTION OF THE DRAWINGS

The above and other aspects and features of the present invention will become readily apparent from the detailed description that follows, with reference to the accompanying drawings, in which:

FIG. 1 is a perspective view illustrating a mobile phone including a photo detecting apparatus according to an embodiment of the present invention;

FIG. 2 is a graph illustrating receiving-light-wavelength characteristics of two photo acceptance units by solid and broken lines;

FIG. 3 is a block diagram showing a circuit configuration of a mobile phone including a photo detecting apparatus according to an embodiment of the present invention;

FIG. 4 is a circuit diagram of a photo detecting apparatus according to an embodiment of the present invention;

FIG. 5 is a circuit diagram of a photo detecting apparatus according to another embodiment of the present invention; and

FIG. 6 is a circuit diagram of a photo detecting apparatus according to another embodiment of the present invention.

### DETAILED DESCRIPTION OF PREFERRED EMBODIMENTS

The present invention will now be described in the context of preferred, but non-limiting embodiments of the invention. Various modifications to the disclosed embodiments may be adopted without departing from the spirit and scope of the invention as defined by the appended claims.

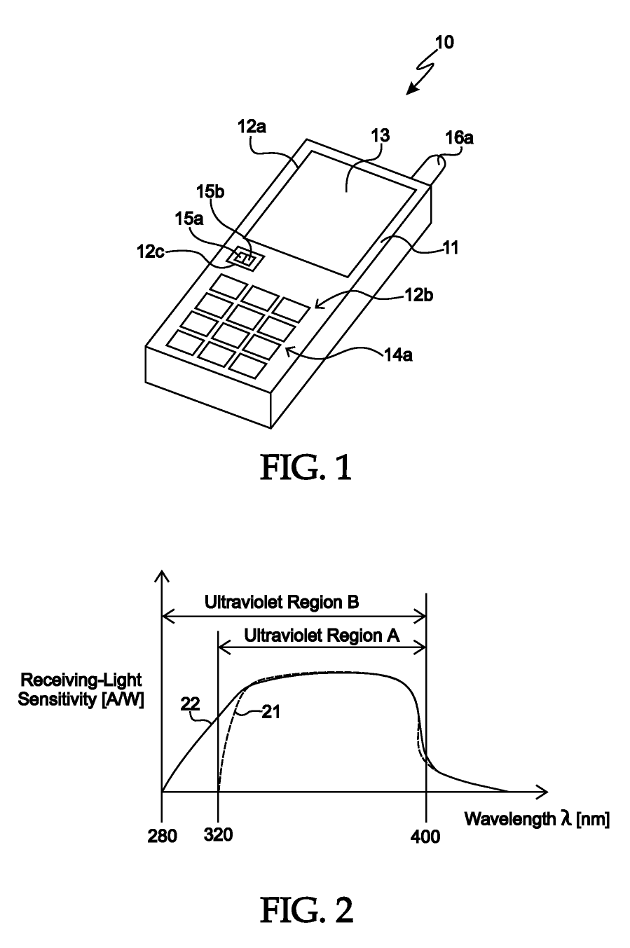

FIG. 1 is a perspective view illustrating an electronic equipment which includes a photo detecting apparatus according to one or more embodiments of the present invention. In the example of this embodiment, the electronic equipment is a mobile phone 10. However, the embodiment is not limited to mobile phones, and may be implemented in other applications. For example, the electronic equipment may be a portable electronic device, such as PDA (personal data assistant), notebook PC (personal computer), a watch, a digital camera, and hybrids of such devices.

As shown in FIG. 1, a plurality of apertures 12a, 12b, 12c are included in a frame 11 of the mobile phone 10. The aperture 12a is located on an upper part of a main surface of the frame 10, and a display unit 13 is fitted into the aperture 12a. Operational buttons 14a fit into the plurality of apertures 12b at a lower part of the main surface of the frame 10.

The aperture 12c functions as a light receiving aperture, and, in this example, is located between the display unit 13 and the operation buttons 14a. Photo acceptance units 15a, 15b (having the mutually-different receiving-light characteristics as described below) are positioned such that light irradiated through the aperture 12c is incident thereon. Preferably, the frame 11 is opaque at least vicinity of the aperture 12c. The photo acceptance units 15a, 15b may, for example, be photodiodes which detect ambient light in the visible and/or ultraviolet spectrum. However, the embodiment is not limited to the detection of visible and/or ultraviolet light, and may instead detect other types of energy (e.g., laser light energy and infra-red energy).

Also illustrated in FIG. 1 is an antenna 16a located at an upper portion of the frame 11.

FIG. 2 is a graph illustrating examples of the spectral response characteristics of the photo acceptance units 15a and 15b. The spectral response characteristic denotes the relationship between photo sensitivity (A/W) and the wavelength λ (nm) of incident light. In FIG. 2, the horizontal axis represents wavelength, and the vertical axis represents photo sensitivity. The dashed-line 21 of FIG. 2 denotes the spectral response characteristic of the photo acceptance unit 15a, while the solid-line of FIG. 2 denotes spectral response characteristic of the photo acceptance unit 15b.

As shown by the graph of FIG. 2, the photo acceptance units 15a and 15b have different spectral response characteristics. That is, in the example of FIG. 2, the photo acceptance unit 15a has a high photo sensitivity in a wavelength region from around 320 nm to around 400 nm (“ultraviolet region A”), while the photo acceptance unit 15b has a high photo sensitivity in a wavelength region from around 280 nm to around 400 nm (“ultraviolet region B”). The photo sensitivity band of the photo acceptance unit 15a is thus narrower than the photosensitivity band of the photo acceptance unit 15b. Also, in the example of FIG. 2, the upper wave-length limit of the ultraviolet regions A and B is roughly the same, i.e., about 400 nm.

As suggested previously, the embodiment is not limited to ultra-violet detections. For example, the photo sensitivities of the photo acceptance units can be in visible-light or infra-red regions.

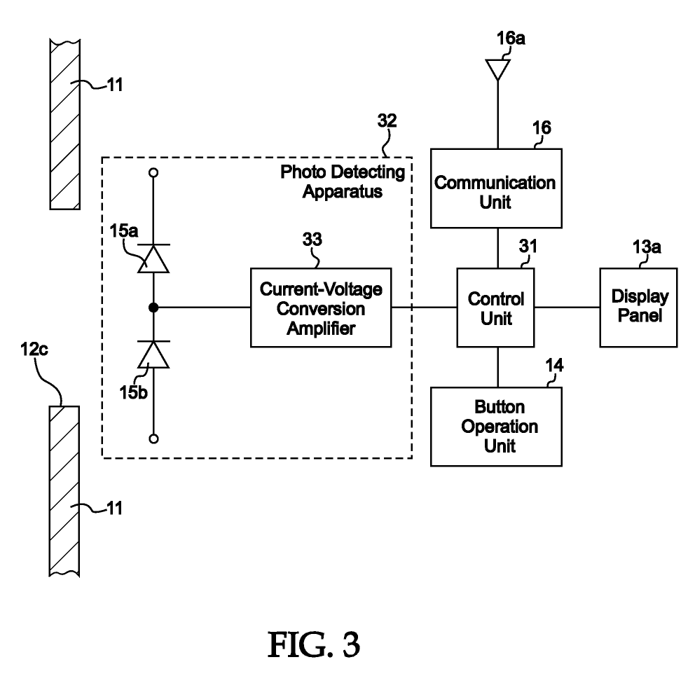

FIG. 3 shows a circuit configuration of the mobile phone 10 including a photo detecting apparatus according to an embodiment of the invention.

As shown in FIG. 3, a display panel 13a composing the display unit 13 (FIG. 1) is connected to a control unit 31. The control unit 31 controls a communication unit 16 (including an antenna 16a) and the display panel 13a according to input control signals from the button operation unit 14. The photo detecting apparatus 32 is further connected to the control unit 31.

The photo detecting apparatus 32 of this embodiment includes the photo acceptance units 15a and 15b which are connected in series with each other and are position to receive incident photo energy through the aperture 12c of the frame 11. In addition, the photo detecting apparatus 32 includes a current-voltage conversion amplifier 33 connected to a junction node between the photo acceptance units 15a and 15b.

The control unit 31 receives a light detection signal converted to a voltage by the current-voltage conversion amplifier 33, and utilizes the light detection signal in controlling at least the display unit 13a. For example, the control unit 31 may control the display unit 13 to display an ultra-violet ray factor indicative of an ultra-violet ray intensity in accordance with the light detection signal. The ultra-violet ray factor can be SPF (Sun Protection Factor) which informs the user of exposure to ultra-violet rays.

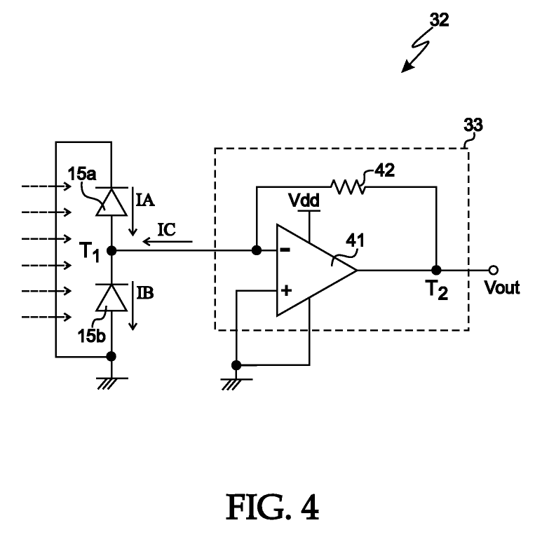

The operation of the photo detecting apparatus 32 of FIG. 3 will be described next in the context of the exemplary embodiments of FIGS. 4˜6, respectively.

FIG. 4 shows a photo detecting apparatus according to an embodiment of the invention.

As shown in FIG. 4, the photo detecting apparatus 32 of this example includes the two photo acceptance units 15a and 15b having different spectral response characteristics (such as those, for example, shown in FIG. 2). The photo acceptance unit 15a and 15b are connected in series at a junction node T1, and the junction node T1 is connected to an input terminal of a current-voltage conversion amplifier 33.

The current-voltage conversion amplifier 33 includes of an operational amplifier 41 and a feedback resistor 42.

An anode of the photo acceptance 15a and a cathode of the photo acceptance 15b are connected to each other via the junction node T1, and a cathode of the photo acceptance 15a and an anode of the photo acceptance 15b are connected to a ground voltage. In other words, in this embodiment, the both ends of the series circuit of the photo acceptance units 15a and 15b are maintained at the ground voltage. In addition, the junction node T1 is connected to a negative input terminal of the operational amplifier 41.

A positive input terminal and a negative power supply terminal of the operational amplifier 41 are connected to the ground voltage. In addition, a positive power supply terminal of the operational amplifier 41 is connected to a power supply Vdd. Furthermore, a negative input terminal and an output terminal of the operational amplifier 41 are connected to each other through a feedback resistor 42.

The dashed arrows of FIG. 4 denote ultraviolet rays incident on the photo acceptance units 15a and 15b. If a wavelength of the incident ultraviolet rays falls within in the ultraviolet region A, a light current Ia flows in the photo acceptance unit 15a in the direction IA correspondingly to the receiving light intensity thereof. If a wavelength of the incident ultraviolet rays falls in the ultraviolet region B, a light current Ib flows in the photo acceptance unit 15b in the direction IB correspondingly to the receiving light intensity thereof. Therefore, a differential current Ic of a difference determined by subtracting the light current Ia from the light current Ib flows in the direction shown by the arrow-head IC and is detected by the current-voltage conversion amplifier 33. The differential current Ic is outputted at an output point T2 as an output voltage V. Furthermore, the output voltage V is outputted from the output terminal Vout to outside the photo detecting apparatus 32.

As explained before, since the light current Ia is a light current corresponding to the ultraviolet ray of the ultraviolet region A, and the light current Ib is a light current corresponding to the ultraviolet ray of the ultraviolet region B, the differential current Ic flowing at the midpoint T1 becomes a current having a value corresponding to a ultraviolet ray having wavelength around from 280 nm to 320 nm (“ultraviolet region C”), and then an ultraviolet ray intensity of the ultraviolet region C is only determined.

In addition, even in the case where a dark current caused by heat from the photo acceptance units 15a, 15b occurs, the above dark current thereof can be cancelled in the differential current Ic of a difference determined by subtracting the light current Ia from the light current Ib.

Consequently, in the photo detecting apparatus according to the first embodiment, it is possible that the light detection signal is outputted correspondingly to the ultraviolet ray intensity in a certain wavelength region (the ultraviolet region C for the present embodiment) without including a filter, and the display data corresponding to the above light detection signal is displayed on the display unit 13.

As explained before, since the photo detecting apparatus according to the first embodiment includes the two photo acceptance units having different spectral response characteristics; the two photo acceptance units being connected to each other through the midpoint and being placed so as to face an aperture of frame of an electronic equipment, and the light detection signal is generated correspondingly to the current intensity detected from the midpoint, it is possible that a light intensity of the external light included in a required wavelength region is detected while restraining the influence of the dark current without shielding the irradiated light.

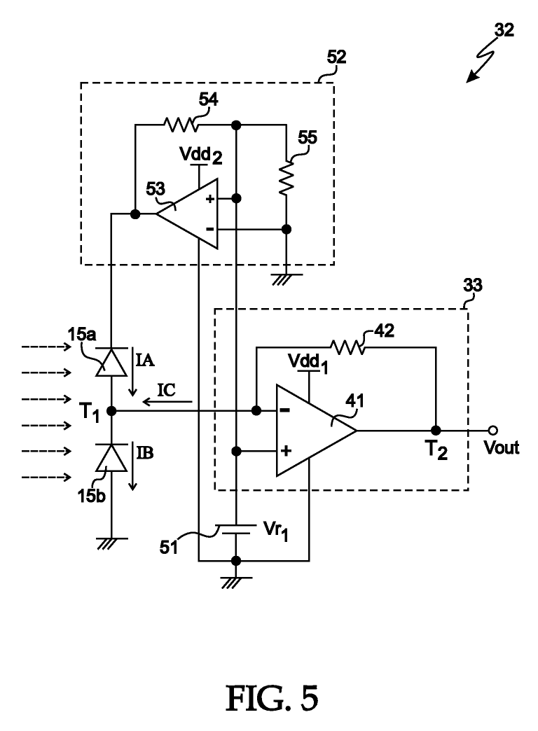

FIG. 5 shows a photo detecting apparatus according to the second embodiment of the invention. In FIG. 5, the elements identical to the ones of the first embodiment are given the same numerals as in the first embodiment.

As shown in FIG. 5, a photo detecting apparatus 32 includes the photo acceptance units 15a, 15b having the spectral response characteristics and being serially connected to each other at a midpoint T1. A current-voltage conversion amplifier 33 converts the current detected from the midpoint T1 to a voltage. A voltage amplifier 52 doubles a reference voltage Vr1 applied from an external power supply 51.

The current-voltage conversion amplifier 33 consists of an operational amplifier 41 and a feedback resistor 42. In addition, a voltage amplifier 52 consists of an operational amplifier 53, a feedback resistor 54, and a feedback resistor 55.

An anode of the photo acceptance 15a and a cathode of the photo acceptance 15b are connected to each other, and an anode of the photo acceptance 15b is connected to a ground voltage and a cathode of the photo acceptance 15a is connected to the voltage amplifier 52. In other words, the both ends of the serial circuit of the photo acceptance units 15a, 15b are maintained at the ground voltage level or a constant reference voltage. In addition, the midpoint T1 for connection between the anode of the photo acceptance 15a and the cathode of the photo acceptance 15b is connected to a negative input terminal of the operational amplifier 41.

Positive input terminals of the operational amplifiers 41, 53 are connected to an external power supply 51. Negative power supply terminals of the operational amplifiers 41, 53 are connected to the ground voltage, and positive power supply terminals thereof are connected to power supplies Vdd1, Vdd2, respectively. A negative input terminal of the operational amplifier 41, and an output terminal of the operational amplifier 41 are connected to each other through the feedback resistor 42. A positive input terminal of the operational amplifier 53 and an output terminal of the operational amplifier 53 are connected to each other through the feedback resistor 54. Furthermore, a positive input terminal of the operational amplifier 53 is also connected to the ground voltage through the feedback resistor 55. In addition, a negative input terminal of the operational amplifier 53 is also connected to the ground voltage.

Operations of the photo detecting apparatus according to the second embodiment of the invention will be explained, as follows. A reference voltage Vr1 applied by the external power supply 51 is inputted to positive input terminals of the operational amplifiers 41, 53. A voltage 2Vr1 being two times large as the reference voltage Vr1 is outputted from the operational amplifier 53, and a reverse-bias voltage of −Vr1 is applied to the photo acceptance units 15a, 15b, respectively.

In the case where an ultraviolet ray is irradiated as shown by the broken arrow, a light current Ia flows in the photo acceptance unit 15a in the direction shown by the arrow-head IA, and a light current Ib flows in the photo acceptance unit 15b in the direction shown by the arrow-head IB, similarly as in the first embodiment. Therefore, a differential current Ic of a difference determined by subtracting the light current Ia from the light current Ib flows at the midpoint T1 in the direction shown by the arrow-head IA, and is detected by the current-voltage conversion amplifier 33. The differential current Ic is outputted from an output terminal Vout through a midpoint T2, after being converted to a voltage.

Consequently, the light detection signal corresponding to a certain wavelength region (that is, the ultraviolet region C) can be outputted, and a display data corresponding to the above light detection signal can be displayed on the display panel 13a, similarly as in the first embodiment.

In addition, as described in the above, there is an advantage that operational characteristics of the case where a reverse bias is applied to each of the photo acceptance units 15a, 15b become more stable than in the case where both ends of the serial circuit of the photo acceptance units 15a, 15b are connected to the ground voltage as in the first embodiment.

As explained before, since the photo detecting apparatus according to the second embodiment includes the two photo acceptance units having different spectral response characteristics; the two photo acceptance units being connected to each other through the midpoint and placed so as to face an aperture of frame of an electronic equipment, and the current is detected from the above midpoint while the serial circuit of the above photo acceptance units is being maintained at the reference voltage and the reverse bias is being applied to each of the photo acceptance units, it is possible that a light intensity of the external light in a required wavelength region is detected while stabilizing the photo acceptance units and removing influence from the dark current without shielding the irradiated light.

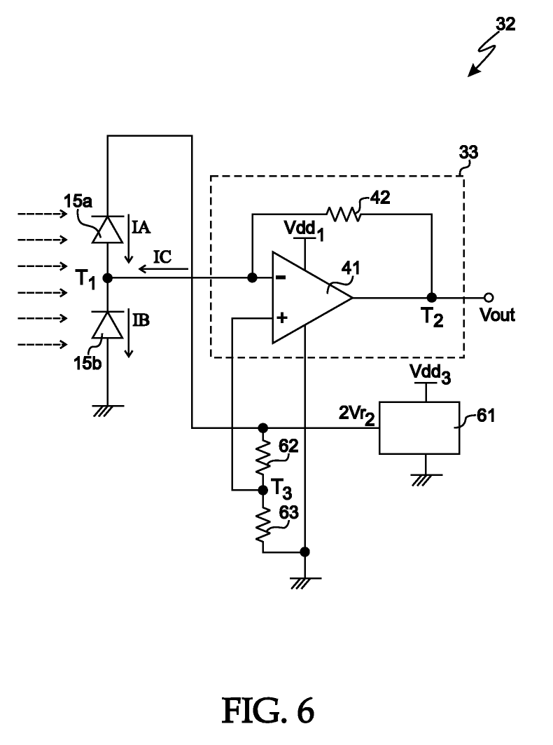

FIG. 6 shows a photo detecting apparatus according to the third embodiment of the invention. In FIG. 6, the elements identical to the ones of the first and second embodiments are given the same numerals as in the first and second embodiments.

As shown in FIG. 6, the photo detecting apparatus 32 includes photo acceptance units 15a, 1 5b having respectively the spectral response characteristics of FIG. 2 and connected serially to each other at a midpoint T1. A current-voltage conversion amplifier 33 converts a current extracted from the midpoint T1 to a voltage. A band gap reference circuit 61 generates a predetermined voltage 2Vr2. The current-voltage conversion amplifier 33 consists of an operational amplifier 41, and a feedback resistor 42.

An anode of the photo acceptance 15a and a cathode of the photo acceptance 15b are connected to each other, and an anode of the photo acceptance 15b is connected to a ground voltage and a cathode of the photo acceptance 15a is connected to the band gap reference circuit 61. In other words, both ends of the serial circuit of the photo acceptance units 15a, 15b are maintained at the ground voltage level or a constant reference voltage. In addition, the midpoint T1 for connection between the anode of the photo acceptance 15a and the cathode of the photo acceptance 15b is connected to a negative input terminal of the operational amplifier 41.

A positive input terminal of the operational amplifier 41 is connected to a midpoint T3 of connecting point between resistors 62, 63, and is connected to the ground voltage through the resistor 63. A negative power supply terminal of the operational amplifier 41 is connected to the ground voltage, and a positive power supply terminal thereof is connected to a power supply Vdd1. The negative input terminal of the operational amplifier 41 and a output terminal of the operational amplifier 41 are connected to each other through the feedback resistor 42. In addition, the band gap reference circuit 61 is connected to the resistor 62, the power supply Vdd3, and the ground voltage.

Operations of the photo detecting apparatus according to the third embodiment will be explained, as follows. The voltage of 2Vr2 generated by the band gap reference circuit 61 is configured to be applied to a cathode of the photo acceptance unit 15a, and then a reverse bias voltage of −Vr2 is applied to each of the photo acceptance units 15a, 15b. In addition, since the resistances of the resistors 62, 63 are the same to each other, a voltage of Vr2 being a half of the voltage 2Vr2 is inputted to the positive input terminal of the operational amplifier 41.

In the case where an ultraviolet ray is irradiated as shown by the broken arrow, a light current Ia flows in the photo acceptance unit 15a in the direction shown by the arrow-head IA, and a light current Ib flows in the photo acceptance unit 15b in the direction shown by the arrow-head IB, similarly as in the first and second embodiments. Therefore, a differential current Ic of a difference determined by subtracting the light current Ia from the light current lb flows at the midpoint T1 in the direction shown by the arrow-head IA, and is detected by the current-voltage conversion amplifier 33. The differential current Ic is outputted from an output terminal Vout through a midpoint T2, after being converted to a voltage.

Consequently, the light detection signal generated by receiving ultraviolet ray in a predetermined wavelength region (that is, the ultraviolet region C) can be outputted, and a display data corresponding to the above light detection signal can be displayed on the display panel 13a, similarly as in the first and second embodiments.

In addition, according to the third embodiment, the voltage generated by the band gap reference circuit 61 is differently from the second embodiment applied to the photo acceptance units 15a, 15b without doubling the above voltage, and there is no additional circuits for using resistor-division by the resistors 62, 63, therefore there is an advantage that the increase of the power consumption can be restrained more than in the second embodiment.

As explained before, since the photo detecting apparatus according to the third embodiment includes the two photo acceptance units having different spectral response characteristics; the two photo acceptance units being connected to each other through the midpoint and being placed so as to face an aperture of frame of an electronic equipment, and a current is detected from the above midpoint while the serial circuit of the above photo acceptance units is being maintained at the reference voltage and a reverse bias is being applied to each of the photo acceptance units, it is possible that a light intensity of the external light included in a predetermined wavelength region is detected while stabilizing the photo acceptance units and removing influence from the dark current without shielding the irradiated light.

What is claimed is:

1. A photo detection apparatus, comprising:
first and second photo detection elements which are connected in series to each other at a junction node, wherein a spectral response characteristic of the first photo detection element is different than a spectral response characteristics characteristic of the second photo detection element;
a signal generating circuit connected to the junction node and generating a light detection signal corresponding to a current extracted at the junction node.

2. The photo detection apparatus of claim 1, wherein the first and second photo detection elements are first and second photodiodes.

3. The photo detection apparatus of claim 2, wherein an anode of the first photodiode is connected to the junction node, and a cathode of the second photodiode is connection to the junction node.

4. The photo detection apparatus of claim 3, wherein the signal generating circuit comprises an operational amplifier having a first input connected to the junction node.

5. The photo detection apparatus of claim 4, wherein the cathode of the first photodiode and the anode of the second photodiode are grounded.

6. The photo detection apparatus of claim 4, further comprising a voltage amplifier connected between a second input of the operational amplifier and the cathode of the first photodiode, wherein the anode of the second photodiode is grounded.

7. The photo detection apparatus of claim 4, further comprising a reference voltage generating circuit which includes an output connected to the cathode of the first photodiode and a second input of the operational amplifier, wherein the anode of the second photodiode is grounded.

8. The photo detection apparatus of claim 7, wherein the output of the reference voltage generating circuit is connect to the second input of the operational amplifier through a voltage divider.

9. The photo detection apparatus of claim 4, wherein a wavelength band of the spectral response characteristic of the first photodiode is narrower than a wavelength band of the spectral response characteristic of the second photodiode.

10. An electronic equipment, comprising a frame including an aperture, and a photo detecting apparatus located within the frame, wherein the photo detecting apparatus comprises:
first and second photo detection elements which receive incident photo energy through the aperture in the frame, wherein the first and second photo detection elements are connected in series to each other at a junction node, and wherein a spectral response characteristic of the first photo detection element is different than a spectral response characteristics characteristic of the second photo detection element;
a signal generating circuit connected to the junction node and generating a light detection signal corresponding to a current extracted at the junction node.

11. The electronic equipment of claim 10, wherein the first and second photo detection elements are first and second photodiodes.

12. The electronic equipment of claim 11, wherein an anode of the first photodiode is connected to the junction node, and a cathode of the second photodiode is connection to the junction node.

13. The electronic equipment of claim 12, wherein the signal generating circuit comprises an operational amplifier having a first input connected to the junction node.

14. The electronic equipment of claim 4, wherein a wavelength band of the spectral response characteristic of the first photodiode is narrower than a wavelength band of the spectral response characteristic of the second photodiode.

15. The electronic equipment of claim 10, further comprising a control unit connected to an output of the photo detection apparatus, and a display and an antenna connected to the control unit.
